(19) United States
(12) Patent Application Publication
(10) Pub. No.: US 2023/0090365 A1
(43) Pub. Date: Mar. 23, 2023

(54) FAN-OUT PACKAGE WITH ANTENNA

(71) Applicant: Texas Instruments Incorporated, Dallas, TX (US)

(72) Inventors: Yiqi Tang, Allen, TX (US); Rajen Manicon Murugan, Dallas, TX (US)

(21) Appl. No.: 17/689,153

(22) Filed: Mar. 8, 2022

Related U.S. Application Data
(60) Provisional application No. 63/247,792, filed on Sep. 23, 2021.

(51) Int. Cl. H01Q 1/22; H01Q 3/44; H01Q 1/38; H01Q 9/04

(52) U.S. Cl. CPC H01Q 1/2283; H01Q 3/44; H01Q 1/38; H01Q 9/0407

(57) ABSTRACT

An electronic device includes a die, a packages structure, and a multilevel redistribution structure having a first via, a first level, a second via, a second level, and passivation material. The first level has a conductive antenna, the first via extends between the conductive antenna and a conductive terminal of the die, and the passivation material extends between the first and second levels. The second via extends through the passivation material between the first and second levels. The second level has a conductive reflector.

### CROSS-REFERENCE TO RELATED APPLICATION

This application claims priority to and benefit of U.S. Provisional Patent Application Ser. No. 63/247,792, filed on Sep. 23, 2021, and titled “mmWave Antenna on Package using Fan-out Technology—FO-WCSP (WLFO)”, the contents of which are hereby fully incorporated by reference.

### BACKGROUND

Modern electronic devices increasingly support high frequency communications functionality. Antennas, such as mmWave antennas continually require smaller form-factor, tight integration and higher frequency with the increased popularity of the fifth-generation technology standard for broadband cellular networks (5G) and internet of things (IoT) technology. However, incorporating a suitable antenna in ever shrinking electronic device packages remains a challenge.

### SUMMARY

In one aspect, an electronic device includes a die, a package structure, and a multilevel redistribution structure. The die has a side that extends in a first plane of orthogonal first and second directions, and a conductive terminal that extends along the side. The package structure encloses a portion of the die. The multilevel redistribution structure has a first via, a first level, a second via, a second level, and passivation material. The first level has first conductive features that include a conductive antenna in a second plane of the first and second directions. The first via extends between the conductive antenna and the conductive terminal along a third direction that is orthogonal to the first and second directions. The passivation material extends between the first and second levels, and the second via extends through the passivation material between the first and second levels along the third direction. The second level has second conductive features that include a conductive reflector in a third plane of the first and second directions, and the third plane is spaced apart from the second plane along the third direction.

In another aspect, a multilevel redistribution structure includes a first level having first conductive features that include a conductive antenna in a plane of a first direction and an orthogonal second direction. The multilevel redistribution structure also includes a first via coupled to the conductive antenna, a second level with second conductive features that include a conductive reflector in another plane of the first and second directions, as well as a passivation material between the first and second levels, and a second via that extends through the passivation material between the first and second levels along a third direction that is orthogonal to the first and second directions.

In a further aspect, a method includes forming a package structure that encloses a portion of a die and exposes a conductive terminal along a side of the die, as well as forming a multilevel redistribution structure on the side of the die, where the multilevel redistribution structure has a first via, a first level, a second via, a second level, and passivation material. The first level has first conductive features that include a conductive antenna in a second plane of the first and second directions, the first via extends between the conductive antenna and the conductive terminal along a third direction that is orthogonal to the first and second directions, the passivation material extends between the first and second levels, the second via extends through the passivation material between the first and second levels along the third direction, the second level has second conductive features that include a conductive reflector in a third plane of the first and second directions, the second conductive features includes a conductive under bump metallization (UBM) structure coupled to the second via, and the third plane spaced apart from the second plane along the third direction.

### BRIEF DESCRIPTION OF THE DRAWINGS

FIG. 1 is a top perspective view of a packaged electronic device including a fan-out wafer chip scale package redistribution structure with an integral antenna and conductive reflector.

FIG. 1A is a side view of the packaged electronic device of FIG. 1.

FIG. 1B is a partial side view of the packaged electronic device of FIG. 1.

FIG. 1C is a partial bottom perspective view of the packaged electronic device of FIG. 1.

FIG. 1D is a top view of the packaged electronic device of FIG. 1.

FIG. 1E is a bottom perspective view of the packaged electronic device of FIG. 1.

FIG. 1F is a partial top view of a model of the antenna and conductive reflector in the packaged electronic device of FIG. 1.

FIG. 1G is a top perspective view of the model of the antenna and conductive reflector in the packaged electronic device of FIG. 1.

FIG. 1H is a graph of simulated antenna response curves for the model of the antenna and conductive reflector in the packaged electronic device of FIG. 1.

FIG. 2 is a flow diagram of a method of fabricating an electronic device.

FIGS. 3-13 are side views of the packaged electronic device of FIG. 1 undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

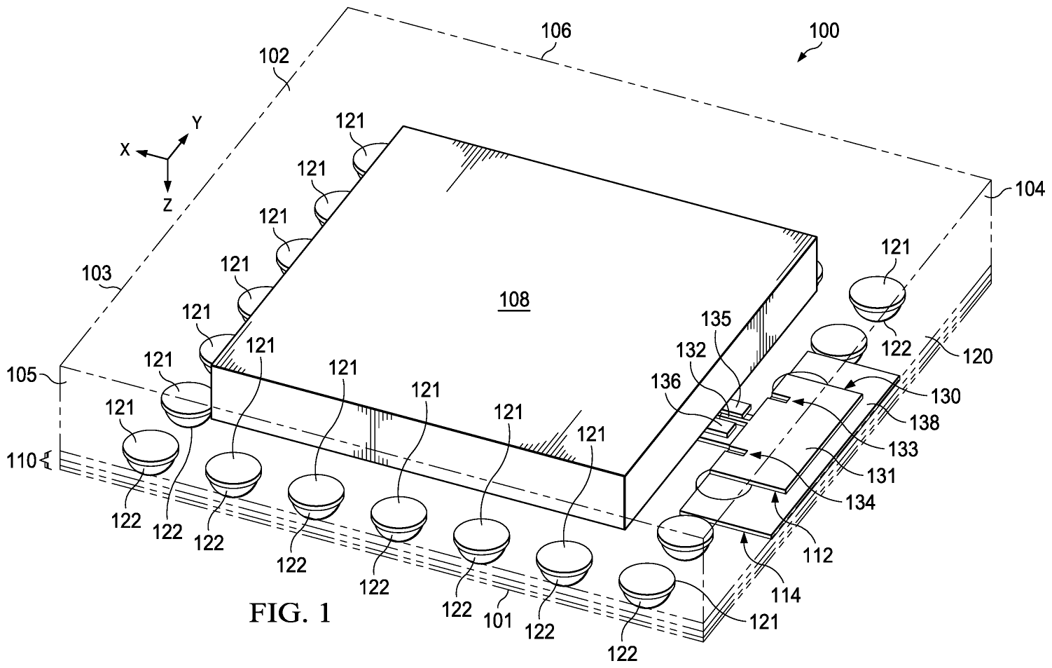

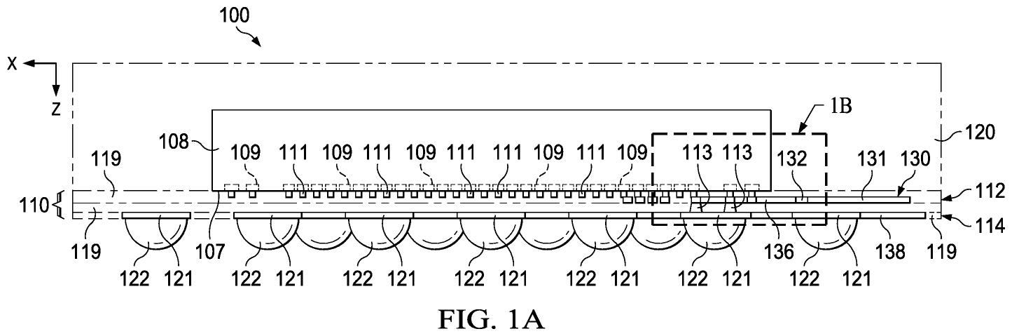

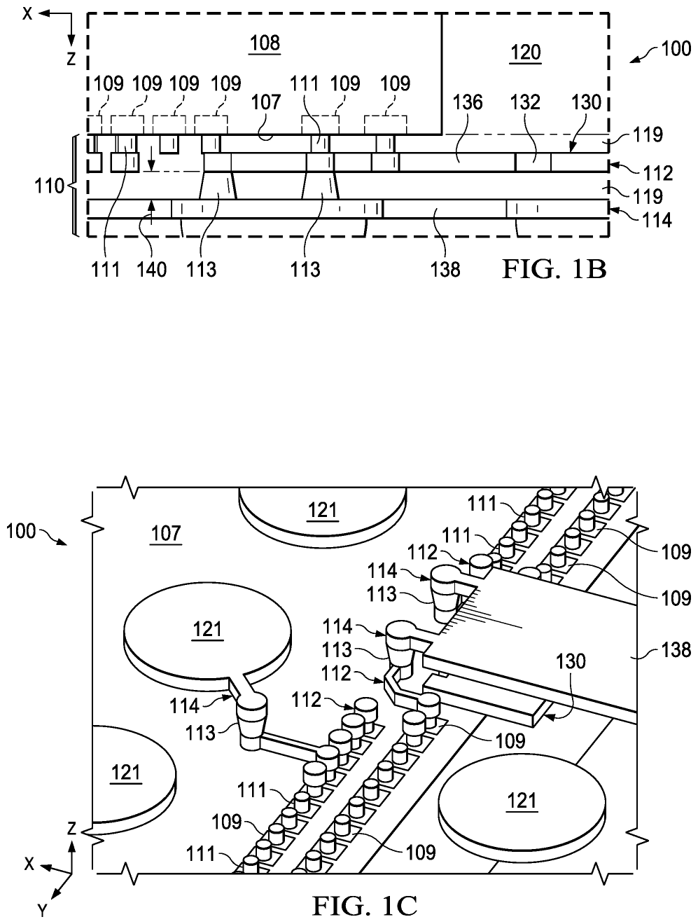

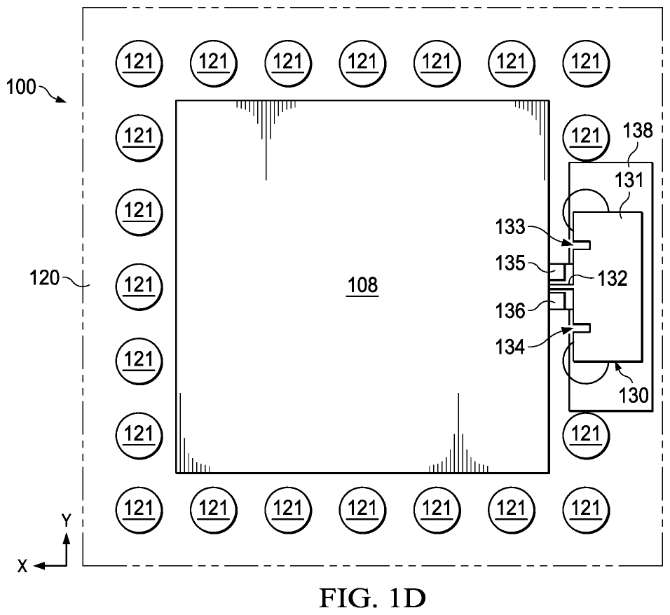

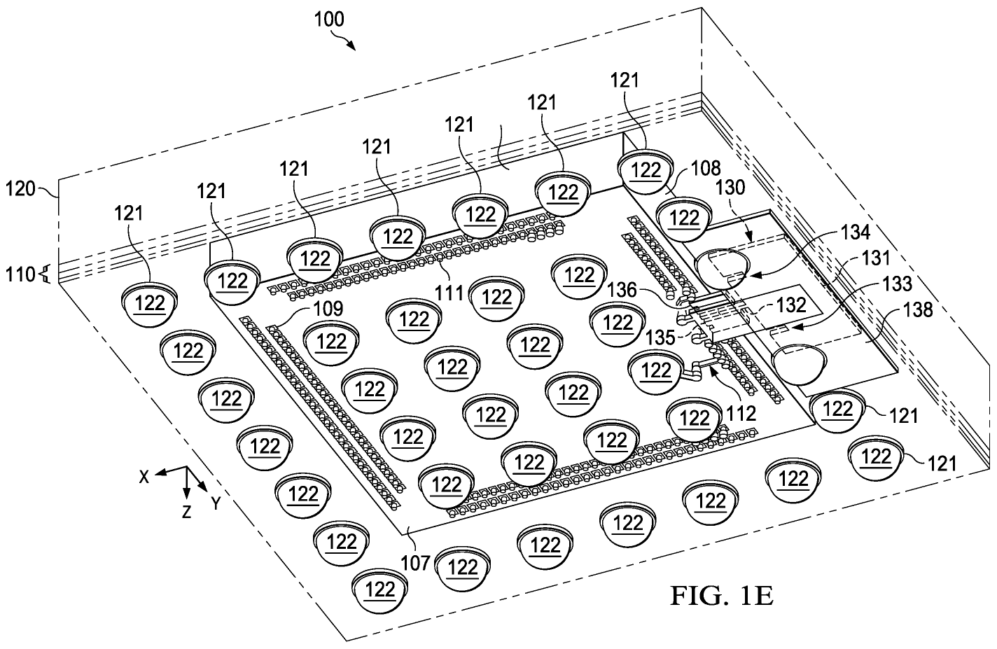

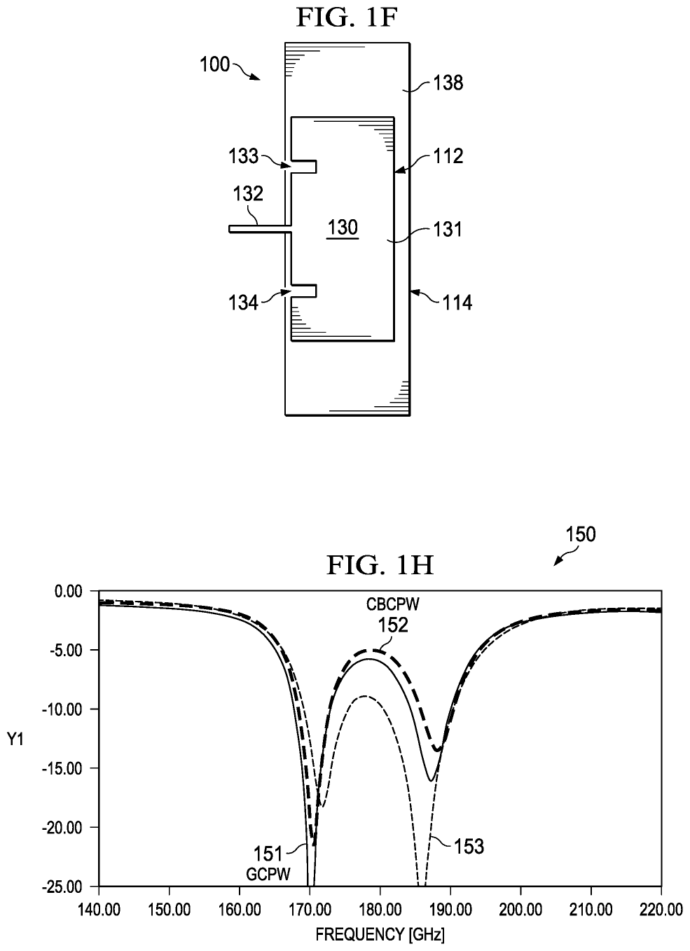

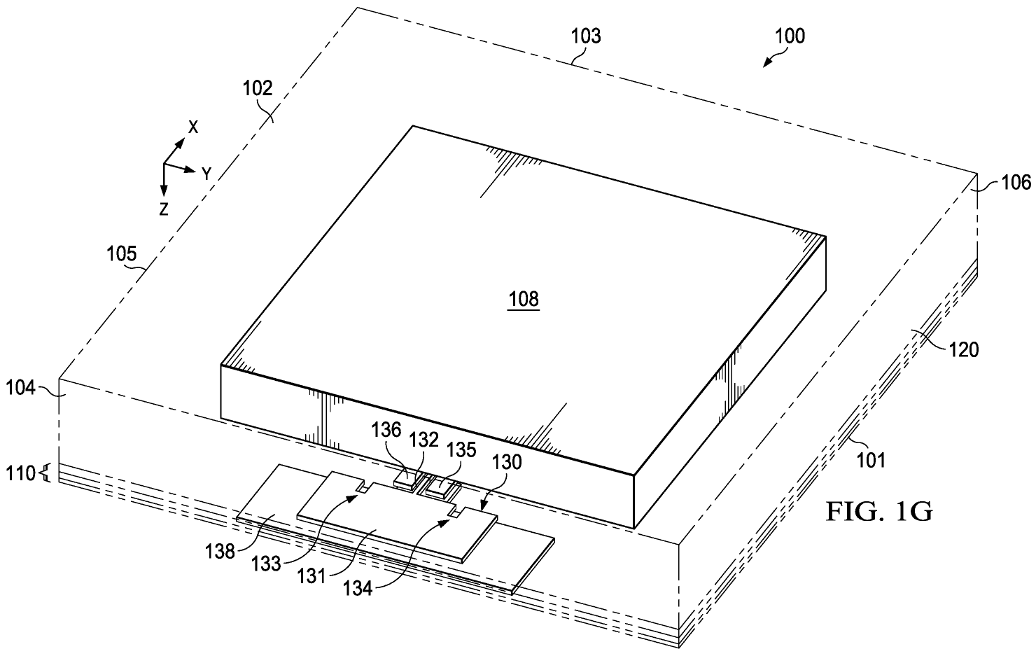

FIGS. 1-1G show a packaged electronic device 100 including a fan-out wafer chip scale (FOWCSP) multilevel redistribution structure 110 with two levels including a conductive antenna 130 and a conductive reflector 138. The packaged electronic device 100 provides an integrated antenna solution to facilitate reduced device form-factor and support higher frequency communications functionality with the benefits of wafer chip scale packaging, for example, in FOWCSP or other package types. The packaged electronic device 100 has a rectangular shape with a first or bottom side 101, a second or top side 102, opposite third and fourth (e.g., left and right) sides 103 and 104, as well as fifth and sixth (e.g., front and back) sides 105 and 106. The electronic device 100 also includes a semiconductor die 108 having conductive terminals 109 shown in FIGS. 1A and 1B (e.g., die bond pads formed as copper pillars or bumps). The multilevel redistribution structure 110 is formed on a side 107 of the semiconductor die 108. The side 107 extends in a first plane of a first direction X and an orthogonal second direction Y. The semiconductor die 108 has conductive terminals 109 that extend along the side 107 of the semiconductor die 108.

The multilevel redistribution structure 110 has multiple levels. In the illustrated example, the multilevel redistribution structure 110 has a first level and a second level. In other implementations, the multilevel redistribution structure 110 has any integer number N levels, where N is greater than 1. The conductive terminals 109 of the die 108 in this example are coupled to respective conductive first vias 111 (e.g., patterned copper or aluminum conductive structures) of the multilevel redistribution structure 110. The first level of the multilevel redistribution structure 110 has first conductive features 112 that include the conductive antenna 130. The conductive antenna 130 extends in a second X-Y plane of the first and second directions X and Y. The second X-Y plane is spaced apart from the first plane along a third direction Z that is orthogonal to the first and second directions X and Y, and the second plane is below the first plane in the orientation shown in FIGS. 1-1G. The multilevel redistribution structure 110 has second vias 113 (e.g., FIGS. 1A-1C) coupled to respective second conductive features 114 of the second level. The second conductive features 114 include the conductive reflector 138. The conductive reflector 138 extends in a third plane of the first and second directions X and Y, and the third plane is spaced apart from and below the second plane along the third direction Z.

The multilevel redistribution structure 110 also includes passivation material 119 that extends between the first and second levels and laterally between conductive features of the multilevel redistribution structure 110. The first vias 111 extend between the conductive antenna 130 and one of the conductive terminals 109 along the third direction Z, and one of the second vias 113 extends through the passivation material 119 between the first and second levels along the third direction Z. The passivation material 119 in one example is or includes polyimide. In this or other examples, the passivation material 119 is or includes dielectric electrically insulating material within and between patterned conductive features of the first and second levels. The electronic device 100 also includes a package structure 120, such as a plastic molded material that encloses a portion of the semiconductor die 108 and extends on an upper portion of the multilevel redistribution structure 110.

The second conductive features 114 include a conductive under bump metallization (UBM) structure 121 that extends through the passivation material 119 between respective ones of the second vias 113 and a respective solder ball 122. The illustrated example is a fan-out multilevel redistribution structure 110, in which one or more of the UBM structures 121 are positioned laterally outward of the semiconductor die 108 to provide a fan-out wafer ship scale redistribution structure (FOWCSP). In this example, moreover, one or more of the UBM structures 121 are beneath the semiconductor die 108, for example, as shown in the bottom views of FIGS. 1C and 1E. In another implementation (not shown), a fan-in only redistribution structure is provided having UBM structures 121 and associated solder balls 122 beneath the semiconductor die 108 without outwardly positioned (e.g., fan-out) UBM structures 121 or solder balls 122. In practice, the solder balls 122 are configured to be soldered to associated conductive pads of a host printed circuit board (PCB, not shown) for structurally supporting the packaged electronic device 100 on the PCB as well as to make conductive electrical connections between various circuit connections of the packaged electronic device 100 and circuitry of the PCB.

The conductive antenna 130 extends above the conductive reflector 138. The conductive antenna 130 has a first portion 131 and a second portion 132 (e.g., a feed line). The second portion 132 of the conductive antenna 130 extends from the respective first via 111 to the first portion 131 along the first direction X, and the first portion 131 is wider than the second portion 132 along the second direction Y. The conductive reflector 138 underlies the conductive antenna 130. The conductive reflector 138 is longer than the conductive antenna 130 in the first direction X, and the conductive reflector 138 is wider than the conductive antenna 130 in the second direction Y. The first portion 131 of the conductive antenna 130 has a rectangular shape in the third plane and includes slots 133 and 134 as shown in FIGS. 1, lE and 1F. As shown in FIGS. 1, 1D and 1E, the first conductive features 112 of the first level include conductive shields 135 and 136 that extend parallel to the second portion 132 of the conductive antenna 130 in the second X-Y plane.

Referring also to FIGS. 1F-1H, the example packaged electronic device 100 includes a two-layer FOWCSP packaging platform with integrated planar antenna and reflector structures in a redistribution layer (RDL) type multilevel redistribution structure 110 formed along a side of the semiconductor die 108. The integration of the conductive reflector 138 in the multilevel redistribution structure 110 facilitates parallel arrangement of the conductive reflector 138 with respect to the conductive antenna 130 and provides advantages in this regard compared with arrangements using a conductive reflector of a printed circuit board (not shown) to which the electronic device is mounted. Moreover, the illustrated example facilitates increased circuit density by allowing positioning of UBM structures 121 and associated solder balls 122 beneath the conductive reflector 138 and the conductive antenna 130, for example, as seen in FIGS. 1, 1A, 1D, and 1E. Compared to a single level FOWCSP that uses the PCB board as a reference, the two-layer FOWCSP packaged electronic device 100 directly uses the conductive reflector 138 of the second level as reference plane to improve immunity to the outside environment.

FIG. 1F shows a partial top view of a model of the conductive antenna 130 and the conductive reflector 138 in the packaged electronic device 100, and FIG. 1G shows a top perspective view of the model. FIG. 1H shows a graph 150 with three-dimensional electromagnetic simulated S Parameter antenna return loss response performance curves 151, 152, and 153 in dB as a function of frequency in GHz for the model of the antenna and conductive reflector in the packaged electronic device of FIG. 1. The curve 151 shows the modeled grounded coplanar waveguide (GCPW) performance of the modeled conductive antenna 130 and associated conductive reflector 138, and the curve 152 represents the simulated conductor-backed coplanar waveguide (CBCPW) performance. The curve 153 shows the E-patch antenna return loss performance of the antenna itself without any driving transmission line (CBCPW or GCPW). The simulated performance corresponds to an e-patch antenna structure as an example, and other implementations can include different antenna types formed in a multilevel redistribution structure.

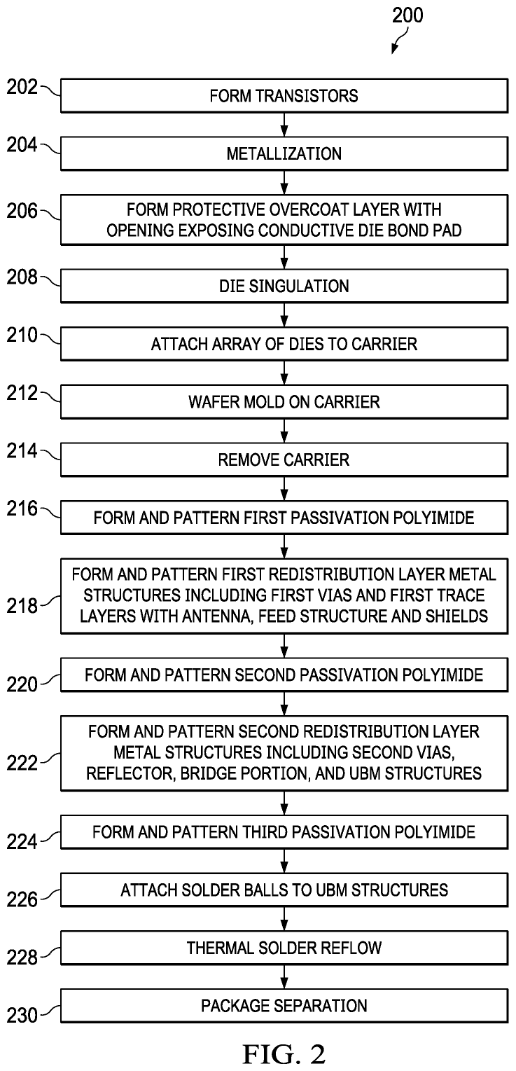

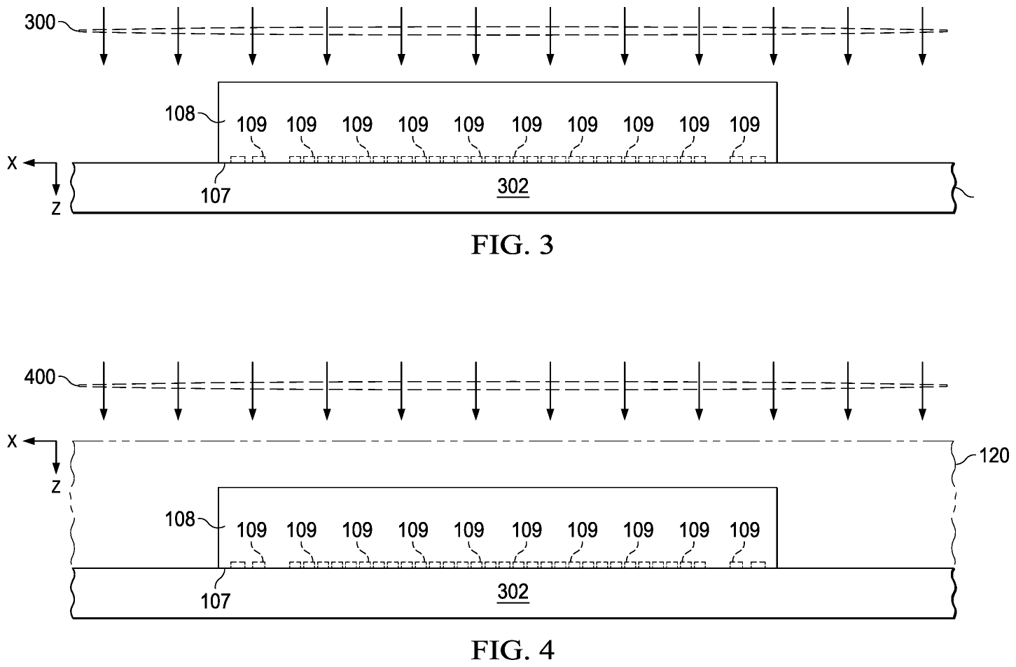

Referring now to FIGS. 2-13, FIG. 2 shows a method 200 of fabricating an electronic device and FIGS. 3-13 show the packaged electronic device 100 of FIG. 1 undergoing fabrication processing according to the method 200. The method 200 includes semiconductor wafer processing with formation of transistors at 202 on or in a starting semiconductor wafer (e.g., a silicon wafer, a silicon-on-insulator (SOI) wafer, etc.), and metallization processing at 204 in order to form a single or multilevel metallization structure with conductive terminals 109 exposed along a top side of the wafer (e.g., copper or aluminum die bond pads formed as pillars or bumps). At 206, a protective overcoat layer (PO) is formed on the top side of the wafer with openings that expose the conductive terminals 109. At 208, individual semiconductor dies 108 are singulated or otherwise separated from the starting wafer, for example, by saw cutting and/or laser cutting.

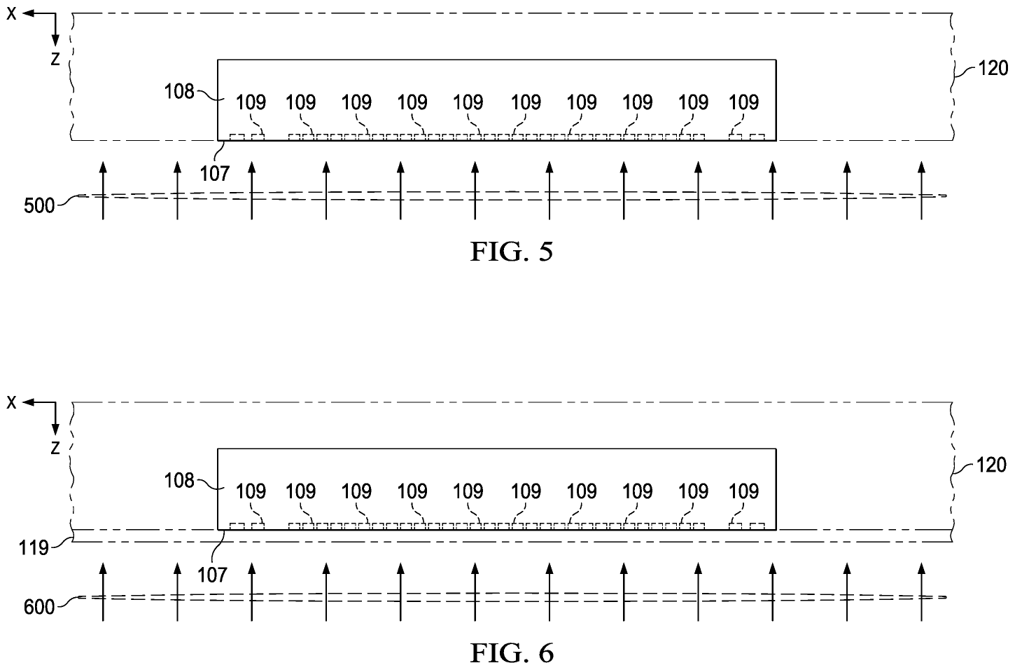

The method 200 continues at 210 in FIG. 2 with attachment of an array of semiconductor dies 108 to a carrier structure. FIG. 3 shows one example, in which a die placement process 300 is performed that attaches the top side of the semiconductor die 108 to an adhesive carrier structure 302 with the conductive terminals 109 facing the carrier structure 302. A package structure 120 is formed at 212. FIG. 4 shows one example, in which a molding process 400 is performed that forms the package structure 120. The molded package structure 120 encloses a portion of the semiconductor die 108. The carrier structure 302 is then removed at 214. FIG. 5 shows one example, in which a removal process 500 is performed to remove the carrier structure 302 and expose the side 107 of the semiconductor die 108 and to expose portions of the conductive terminals 109 and the protective overcoat layer of the semiconductor die 108.

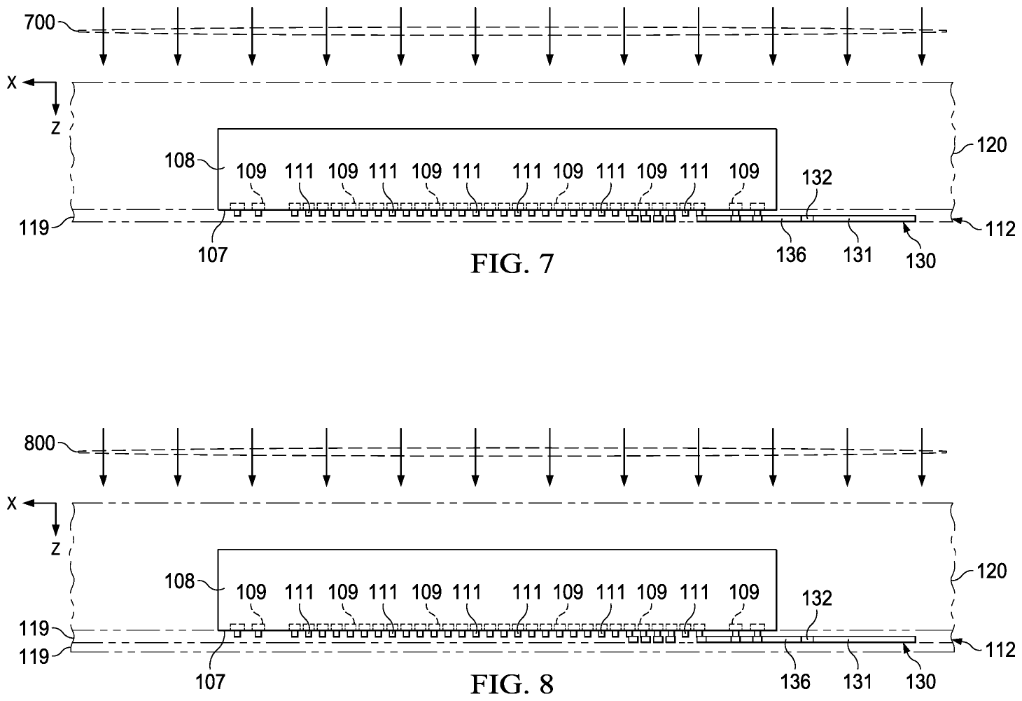

The multilevel redistribution structure 110 is formed at 216-224 on the side 107 of the die 108. In one example, a first passivation polyimide material layer 119 is formed on the side 107 of the semiconductor die 108 and patterned at 216. FIG. 6 shows one example, in which a process 600 is performed that forms a first passivation polyimide material layer 119 on the side 107 of the semiconductor die 108 and patterns the polyimide material 119 to include holes for prospective first vias. At 218, patterned first redistribution layer metal structures are formed including the first vias 111 and the first trace layer structures including the conductive antenna portions 131 and 132 as well as any included conductive shields 135 and 136. FIG. 7 shows one example, in which a process 700 is performed that deposits copper, aluminum, or other suitable conductive metal material on the first polyimide layer 119, and the deposited metal is patterned to form the first vias 111 and other first conductive features 112 including the conductive antenna 130 on the first passivation material layer 119.

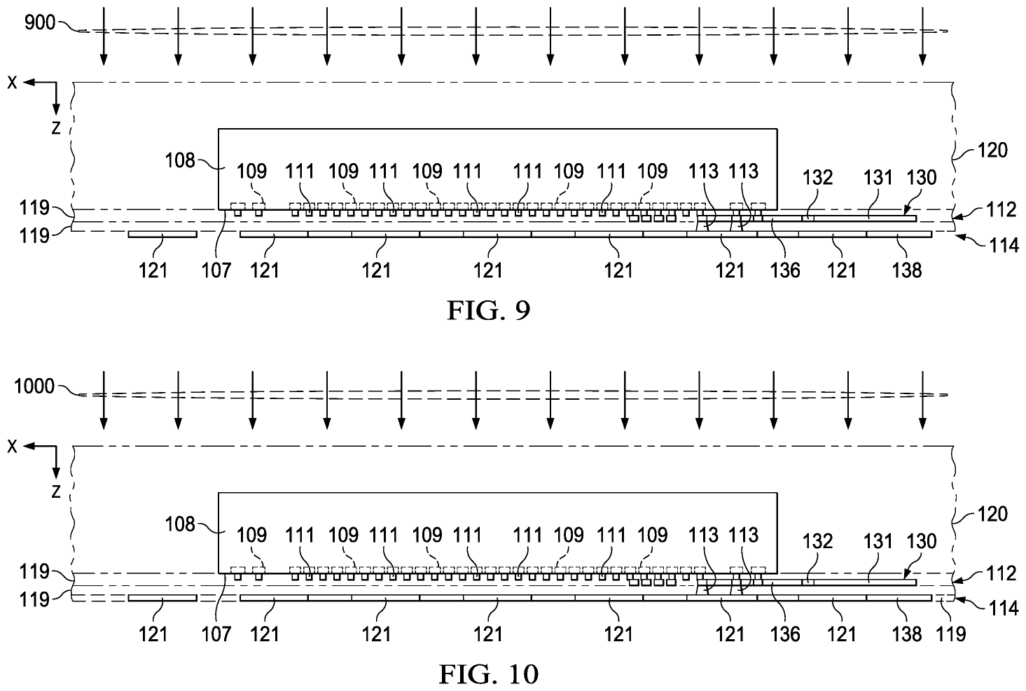

At 220 in FIG. 2, a second passivation polyimide layer 119 is formed on the first level of the multilevel redistribution structure 110. FIG. 8 shows one example, in which a process 800 is performed that forms a second passivation polyimide material layer 119 on the previous polyimide material layer 119 and over the first conductive features 112 of the first level. The process 800 in one example also patterns portions of the second passivation polyimide layer 119 to form holes for prospective second vias. At 222, patterned second redistribution layer metal structures are formed and patterned. FIG. 9 shows one example, in which a process 900 is performed that deposits copper, aluminum, or other suitable conductive metal material on the second polyimide layer 119. The process 900 also patterns the deposited metal to form the second conductive features 114 including the second vias 113, the UBM structures 121, and the conductive reflector 138 of the second level. At 224, a third passivation polyimide material layer is formed and patterned. FIG. 10 shows one example, in which a process 1000 is performed that forms a third passivation polyimide layer 119 on the previous polyimide material layer 119 and over the second vias 113, the UBM structures 121, and the conductive reflector 138. The process 1000 also patterns the third polyimide material layer 119 to expose portions of the second vias 113 and the UBM structures 121, while covering the conductive reflector 138.

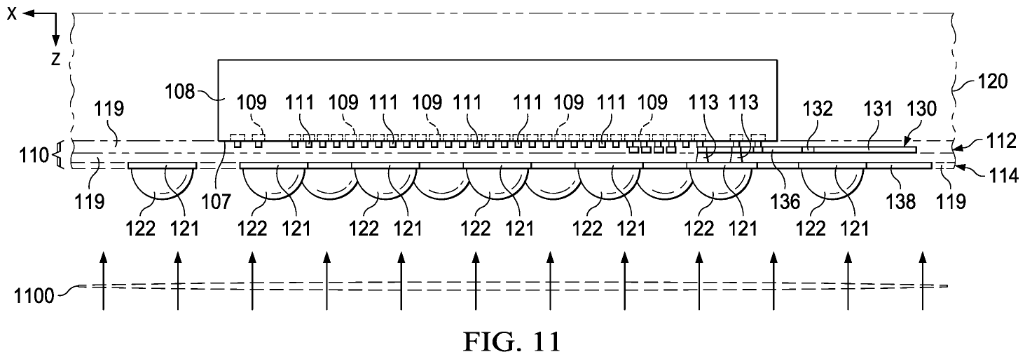

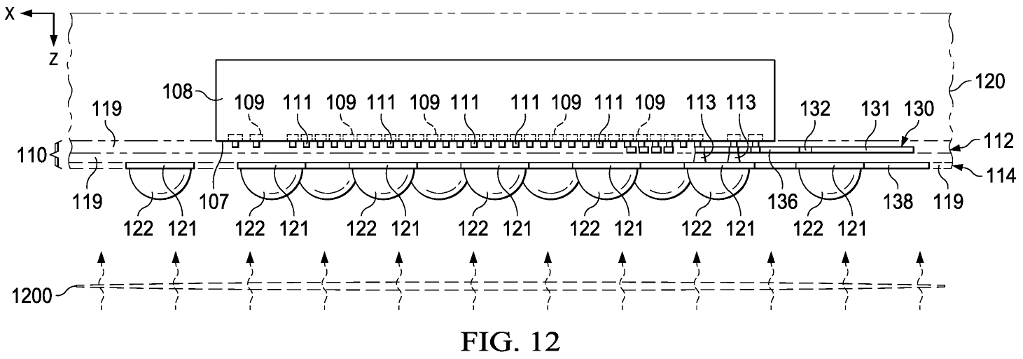

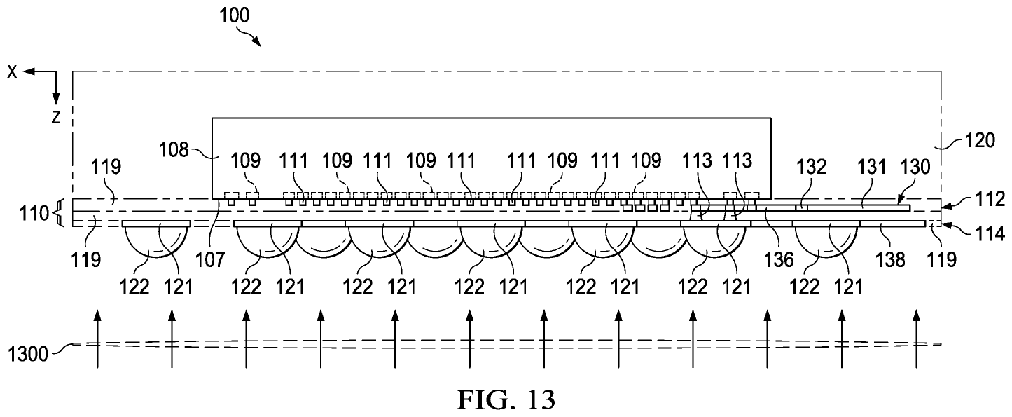

The method 200 continues at 226 in FIG. 2 with solder ball attachment. FIG. 11 shows one example, in which a solder ball attach process 1100 is performed that attaches a solder ball or other solder structure 122 (e.g., a generally round solder ball) on the conductive UBM structures 121, for example, using a stencil (not shown) that aligns the respective attached solder balls 122 with the center of the associated UBM structure 121. The method 200 further includes thermal solder reflow processing at 228. FIG. 12 shows one example, in which a thermal reflow (e.g., heating) process 1200 is performed that reflows the solder ball to spread out the solder ball 122 on the associated UBM structure 121. The method 200 in one example also includes die separation or singulation at 230 to separate individual packaged electronic devices 100 from the panel structure used to concurrently form multiple packaged electronic devices and associated multilevel redistribution structures 110. FIG. 13 shows one example, in which the processed panel is cut by a process 1300 (e.g., using a saw and/or laser, not shown) to form the finished packaged electronic device 100.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a die having a side and a conductive terminal, the side extending in a first plane of a first direction and an orthogonal second direction, and the conductive terminal extending along the side;
a package structure that encloses a portion of the die; and
a multilevel redistribution structure having a first via, a first level, a second via, a second level, and passivation material, the first level having first conductive features that include a conductive antenna in a second plane of the first and second directions, the first via extending between the conductive antenna and the conductive terminal along a third direction that is orthogonal to the first and second directions, the passivation material extending between the first and second levels, the second via extending through the passivation material between the first and second levels along the third direction, the second level having second conductive features that include a conductive reflector in a third plane of the first and second directions, and the third plane spaced apart from the second plane along the third direction.

2. The electronic device of claim 1, wherein: the electronic device further comprises a solder ball; and the second conductive features include a conductive under bump metallization (UBM) structure that extends through the passivation material between the second via and the solder ball.

3. The electronic device of claim 2, wherein:
the conductive antenna extends above the conductive reflector;
the conductive reflector is longer than the conductive antenna in the first direction; and
the conductive reflector is wider than the conductive antenna in the second direction.

4. The electronic device of claim 3, wherein:
the conductive antenna has a first portion and a second portion;
the second portion extends from the first via to the first portion along the first direction; and
the first portion is wider than the second portion along the second direction.

5. The electronic device of claim 2, wherein the UBM structure is laterally outward of the die.

6. The electronic device of claim 1, wherein:
the conductive antenna extends above the conductive reflector;
the conductive reflector is longer than the conductive antenna in the first direction; and
the conductive reflector is wider than the conductive antenna in the second direction.

7. The electronic device of claim 6, wherein:
the conductive antenna has a first portion and a second portion;
the second portion extends from the first via to the first portion along the first direction; and
the first portion is wider than the second portion along the second direction.

8. The electronic device of claim 1, wherein:
the conductive antenna has a first portion and a second portion;
the second portion extends from the first via to the first portion along the first direction; and
the first portion is wider than the second portion along the second direction.

9. The electronic device of claim 8, wherein the first portion has a rectangular shape in the third plane.

10. The electronic device of claim 8, wherein the first conductive features include conductive shields that extend parallel to the second portion of the antenna in the second plane.

11. A multilevel redistribution structure, comprising:
a first level having first conductive features that include a conductive antenna in a plane of a first direction and an orthogonal second direction;
a first via coupled to the conductive antenna;
a second level having second conductive features that include a conductive reflector in another plane of the first and second directions;
a passivation material extending between the first and second levels; and
a second via extending through the passivation material between the first and second levels along a third direction that is orthogonal to the first and second directions.

12. The multilevel redistribution structure of claim 11, further comprising a solder ball;
wherein the second conductive features include a conductive under bump metallization (UBM) structure that extends through the passivation material between the second via and the solder ball.

13. The multilevel redistribution structure of claim 11, wherein:
the conductive antenna extends above the conductive reflector;
the conductive reflector is longer than the conductive antenna in the first direction; and
the conductive reflector is wider than the conductive antenna in the second direction.

14. The multilevel redistribution structure of claim 11, wherein:
the conductive antenna has a first portion and a second portion;
the second portion extends from the first via to the first portion along the first direction; and
the first portion is wider than the second portion along the second direction.

15. The multilevel redistribution structure of claim 14, wherein the first portion has a rectangular shape in the other plane.

16. The multilevel redistribution structure of claim 14, wherein the first conductive features include conductive shields that extend parallel to the second portion of the antenna in the plane.

17. A method of fabricating an electronic device, the method comprising:
forming a package structure that encloses a portion of a die and exposes a conductive terminal along a side of the die in a first plane of orthogonal first and second directions; and
forming a multilevel redistribution structure on the side of the die, the multilevel redistribution structure having a first via, a first level, a second via, a second level, and passivation material, the first level having first conductive features that include a conductive antenna in a second plane of the first and second directions, the first via extending between the conductive antenna and the conductive terminal along a third direction that is orthogonal to the first and second directions, the passivation material extending between the first and second levels, the second via extending through the passivation material between the first and second levels along the third direction, the second level having second conductive features that include a conductive reflector in a third plane of the first and second directions, the second conductive features including a conductive under bump metallization (UBM) structure coupled to the second via, and the third plane spaced apart from the second plane along the third direction.

18. The method of claim 17, further comprising:
attaching a solder ball to the UBM structure.

19. The method of claim 18, wherein forming the multilevel redistribution structure includes:
forming and patterning a first passivation material layer on the side of the die;
forming and patterning first redistribution layer metal structures including the first via and the first conductive features on the first passivation material layer;
forming and patterning a second passivation material layer on the first redistribution layer metal structures;
forming and patterning second redistribution layer metal structures including the second via and the second conductive features on the second passivation material layer; and
forming and patterning a third passivation material layer on the second redistribution layer metal structures.

20. The method of claim 17, wherein forming the multilevel redistribution structure includes:
forming and patterning a first passivation material layer on the side of the die;
forming and patterning first redistribution layer metal structures including the first via and the first conductive features on the first passivation material layer;
forming and patterning a second passivation material layer on the first redistribution layer metal structures;
forming and patterning second redistribution layer metal structures including the second via and the second conductive features on the second passivation material layer; and
forming and patterning a third passivation material layer on the second redistribution layer metal structures.
